(19) United States
(12) Patent Application Publication
(10) Pub. No.: US 2013/0014697 A1
(43) Pub. Date: Jan. 17, 2013

(54) Container Having Multiple Compartments Containing Liquid Material for Multiple Wafer-Processing Chambers

(71) Applicant: Hiroki Kanayama, Nagaoka-shi (JP)

(72) Inventor: Hiroki Kanayama, Nagaoka-shi (JP)

(73) Assignee: ASM JAPAN K.K., Tokyo (JP)

(21) Appl. No.: 13/181,407

(22) Filed: Jul. 12, 2011

(51) Int. Cl. C23C 16/455; C23C 16/52; C23C 16/50

(52) U.S. Cl. 118/712

(57) ABSTRACT

A container for containing a liquid material for processing a wafer includes: a container body; a divider dividing the interior of the container body and defining compartments fluid-tightly sealed off from each other except for bottom portions of the compartments; gas inlet ports for introducing gas to the respective compartments and gas outlet ports for discharging gas from the respective compartments; and a liquid level sensor provided in one of the compartments for keeping a liquid surface of a liquid material above the bottom portions when the container is in use conditions.

### BACKGROUND OF THE INVENTION

1. Field of the Invention

The present invention generally relates to a container for storing a liquid material for processing a wafer, particularly to such a container for supplying gas of the liquid material to multiple reactors.

2. Description of the Related Art

Conventionally, to use one liquid material as a precursor, one liquid material container storing the liquid material is required for one reactor for CVD or ALD. Thus, if there are multiple reactors, the same number of liquid material containers as that of the reactors is required. Further, if multiple liquid materials are used for processing, the same number of liquid material containers as that of the liquid materials is required. FIG. 3 is a schematic view of a container for storing a liquid material. A container body 56 enclosed by a precursor bottle heater 101 stores a liquid material 58 supplied thereto through a charge port 100 and is provided with a gas inlet port 68 and a gas outlet port 67, both of which have an on-off valve 47. The amount of the liquid material is adjusted by checking the surface level of the liquid material using a liquid level sensor 52 which has level sensing points 51. A carrier gas is introduced into the container body 56 through the gas inlet port 68, and the carrier gas is discharged from the container body 56 together with vaporized liquid material through the gas outlet port 67. Recently, in order to improve productivity or throughput, multiple reactors are disposed in one platform. In the multiple-reactor platform, the number of required liquid material containers is a product of the number of liquid materials used and the number of reactors, increasing the footprint of the multiple-reactor platform.

The reason that one liquid material container is required for one reactor is that if one liquid material container is shared by two or more reactors, it is difficult to uniformly introduce vaporized liquid material to the multiple reactors at the same concentration when splitting a gas flow into multiple gas flows upstream of the reactors or when sharing a carrier gas inlet for multiple gas outlets of the liquid material container. Since the liquid material is a precursor constituting an element or elements of the main chemical structure of a film, if the quantity of vaporized liquid material taken by carrier gas from the liquid material container and introduced into the multiple reactors varies depending on the reactor even to a small degree, the quality of films is easily affected.

Any discussion of problems and solutions involved in the related art has been included in this disclosure solely for the purposes of providing a context for the present invention, and should not be taken as an admission that any or all of the discussion were known at the time the invention was made.

### SUMMARY OF THE INVENTION

Some embodiments resolve at least one of the problems. Some embodiments provide a container for containing a liquid material for processing a wafer, comprising: (i) a container body; (ii) at least one divider vertically dividing the interior of the container body and defining compartments fluid-tightly sealed off from each other except for bottom portions of the compartments where the dividers have openings, said bottom portions being fluid-communicated with each other via the openings; (iii) gas inlet ports for introducing gas to the respective compartments and gas outlet ports for discharging gas from the respective compartments, wherein one gas inlet port and one gas outlet port are attached to and fluid-communicated with a top portion of each compartment, said gas outlet ports being adapted to be connected to respective wafer-processing chambers; and (iv) a liquid level sensor provided in one of the compartments for keeping a liquid surface of a liquid material above the bottom portions when the container is in use conditions.

In some embodiments, the gas outlet ports are connected to the respective wafer-processing chambers. In some embodiments, the gas inlet ports are connected to respective mass flow controllers of carrier gas. Due to the dividers, gas phases of the compartments are completely isolated from each other whereas liquid phases of the compartments are liquid-communicated with each other, a gas ratio of carrier gas to vaporized liquid material discharged from the container to each reactor can be substantially constant, and the footprint and the cost of the container(s) are substantially reduced as compared with those of conventional containers.

In some embodiments, the openings have upper edges which are disposed under the lowest liquid level measurable by the liquid level sensor.

In some embodiments, the peripheries of the dividers are welded to an inner wall of the container body except for bottom portions of the dividers so as to fluid-tightly seal off the compartments from each other except for the bottom portions of the compartments.

In some embodiments, the compartments except for the bottom portions are substantially identical in their dimensions.

In some embodiments, the container body is provided with a heater disposed outside the container body. In some embodiments, the compartments have shapes such that thermal energy from the heater is substantially equally supplied to each compartment.

In some embodiments, the container body has liquid material inlet ports which are provided in the respective compartments.

In some embodiments, the compartments store a liquid material whose liquid level is above upper edges of the openings of the dividers.

In some embodiments, each of the gas inlet and gas outlet ports is provided with an on-off valve.

In some embodiments, one of the compartments is provided with the liquid level sensor, and all the other compartment(s) are/is provided with no liquid level sensors.

In some embodiments, the compartments consist of a total of four compartments.

Some embodiments provide a container for containing a liquid material for processing a wafer, comprising: (a) a container body storing a liquid material; (b) at least one divider vertically extending from a top surface of the container body toward a bottom surface of the container body to a certain extent such that the divider divides the interior of the container body and defines compartments gas-tightly sealed off from each other except for bottom portions of the compartments, wherein gas phases of the liquid material in upper portions of the compartments are gas-tightly isolated and discrete from each other, whereas liquid phases under the gas phases of the liquid material are liquid-communicated with each other; (c) gas inlet ports for introducing gas to the respective compartments and gas outlet ports for discharging gas from the respective compartments, wherein one gas inlet port and one gas outlet port are attached to and gas-communicated with the upper portion of each compartment, said gas outlet ports being connected to respective wafer-processing chambers; and (d) a liquid level sensor provided in one of the compartments for keeping a liquid surface of the liquid material above the bottom portions.

In some embodiments, one of the compartments is provided with the liquid level sensor, and all the other compartment(s) are/is provided with no liquid level sensors.

In some embodiments, the gas inlet ports are connected to respective mass flow controllers of carrier gas.

In some embodiments, the liquid level sensor has a lowest sensing point which is above the bottom portions of the compartments.

In some embodiments, the liquid material is a precursor for forming a film on a semiconductor wafer.

Some embodiments provide a wafer-processing apparatus comprising: (A) wafer-processing chambers being discrete from each other, each chamber being structured to process a wafer; (B) primary gas lines connected to the wafer-processing chambers; (C) secondary gas lines connected to the wafer-processing chambers; and (D) at least any one of the foregoing containers wherein the gas outlet ports are connected to the respective wafer-processing chambers via the primary gas lines.

In some embodiments, the wafer-processing chambers are plasma CVD reactors.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1 is a schematic representation of a PEALD apparatus for depositing a film according to an embodiment of the present invention.

FIG. 2 is a schematic cross sectional view of the container according to an embodiment of the present invention.

FIG. 3 is a schematic cross sectional view of a conventional container.

### DETAILED DESCRIPTION OF EMBODIMENTS

In the disclosure, “liquid material” may refer to a material or materials which is/are normally in liquid form at room temperature under the standard atmospheric pressure. The liquid material may be a precursor which constitutes an element or elements of film to be deposited on a wafer. In this disclosure, “gas” may include vaporized solid and/or liquid and may be constituted by a mixture of gases. In this disclosure, the reactive gas, the additive gas, and the hydrogen-containing silicon precursor may be different from each other or mutually exclusive in terms of gas types, i.e., there is no overlap of gas types among these categories. Gases can be supplied in sequence with or without overlap.

In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers.

In the present disclosure where conditions and/or structures are not specified, the skilled artisan in the art can readily provide such conditions and/or structures, in view of the present disclosure, as a matter of routine experimentation. Also, in the present disclosure including the examples described later, the numbers applied in specific embodiments can be modified by a range of at least ±50% in some embodiments, and the ranges applied in some embodiments may include or exclude the lower and/or upper endpoints. Further, the numbers include approximate numbers, and may refer to average, median, representative, majority, etc. in some embodiments.

In all of the disclosed embodiments, any element used in an embodiment can interchangeably or additionally be used in another embodiment unless such a replacement is not feasible or causes adverse effect or does not work for its intended purposes. Further, the present invention can equally be applied to apparatuses and methods.

In the disclosure, “substantially identical”, “substantially equal”, or the like may refer to an immaterial difference or a difference recognized by a skilled artisan such as those of less than 10%, less than 5%, less than 1%, or any ranges thereof in some embodiments. Also, in the disclosure, “substantially smaller”, “substantially different”, or the like may refer to a material difference or a difference recognized by a skilled artisan such as those of at least 1%, 5%, 10%, 20%, 30%, 40%, 50%, 60%, 70%, 80%, or any ranges thereof in some embodiments.

In this disclosure, any defined meanings do not necessarily exclude ordinary and customary meanings in some embodiments.

The embodiments will be explained with respect to preferred embodiments. However, the present invention is not limited to the preferred embodiments

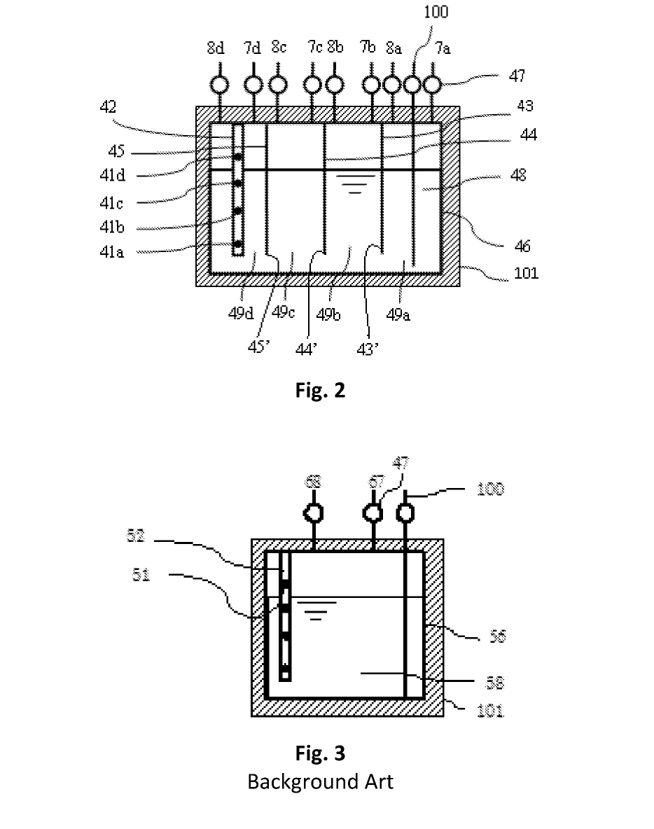

Embodiments are explained with reference to the drawings which are not intended to limit the present invention. FIG. 2 is a schematic cross sectional view of a container according to an embodiment.

In this embodiment, the container body 46 has four compartments 49a, 49b, 49c, 49d which are sealed off from each other by dividers 43, 44, 45. The dividers 43, 44, 45 are made of a material, such as stainless steel or any other suitable material which has substantial resistance to a liquid material stored in the container body or which is the same as that of the container body. The divider has a plate-shape and the outer peripheries except for the bottom are welded to an inner wall of the container. The divider can be liquid-tightly attached to the inner wall of the container by any other suitable means including an adhesive, etc. Alternatively, the dividers and the container can be molded together. Further, alternatively, the container can be constituted by multiple smaller containers (e.g., modules) having open bottoms, which are attached together, and a bottom container having an open top, on which the multiple smaller containers are mounted and sealed. In this embodiment, the liquid material is supplied to the container body through a charge port 100 and is kept at a predetermined temperature using a precursor bottle heater 101 surrounding the container body.

The compartments 49a, 49b, 49c, 49d are liquid-communicated with each other via their bottom portions, constituting a bottom channel, since each divider is shorter than the height of the container body 46, forming an opening at the bottom. The dividers 43, 44, 45 have lower edges 43′, 44′, 45′, respectively, which define the openings together with the bottom surface of the container body 46. In some embodiments, the dividers completely seal off the compartments from each other except for holes formed at their bottom portions of the dividers. The bottom portions of the compartments are liquid-communicated with each other through the holes. In some embodiments, the distance between the bottom surface of the container body 46 and the lower edges 43′, 44′, 45′ may be about 5% to about 40% of the height of the container body 46 (typically less than about 20%). Also, in some embodiments, the above percentages may apply to the area of the opening (or a hole/holes) of the divider relative to the area of a cross section of the container body where the divider is disposed. In some embodiments, two to ten vertically-defined compartments are formed (typically two to eight, more typically four).

In some embodiments, the compartments have substantially the same shape and substantially the same volume or capacity or dimensions so that thermal deviation among the compartments can be inhibited. In some embodiments, the shape of the container body is substantially a laterally-long rectangular parallelepiped where the compartments are formed by disposing the dividers along a direction perpendicular to the lateral direction. In some embodiments, the shape of the container body is substantially a column or pillar where the compartments are formed by disposing the dividers along a radial direction. When a heater for heating a liquid material stored in the container body is provided in the container body, the compartments are shaped so that substantially equal thermal energy can be applied to each compartment from the heater (e.g., a contact area of each compartment with the heater is equalized). In some embodiments, in order to equally heat each compartment, a heater is placed exclusively on two side walls facing all the compartments, bottom portion, and/or top portion, rather than placing a heater all the sides, so that it can be avoided to heat the side compartments more than the middle compartments and a heating area through which heat is transferred to the precursor stored in each compartment can be equal.

In some embodiments, a liquid level sensor 42 is provided in one of the compartments of the container body (e.g., the compartment 49d). Since the container body has the bottom channel where the compartments are communicated with each other, and the liquid material moves so as to keep the surface level of the liquid material constant among the compartments (the openings are formed to realize this), one liquid level sensor provided in one of the compartments is sufficient, and the other compartments have no liquid level sensors. The liquid level sensor 42 has sensing points 41a, 41b, 41c, 41d vertically distributed at substantially equal intervals. In some embodiments, the lowest sensing point 41a is set above the lower edges 43′, 44′, 45′ so that the liquid level of the liquid material does not get lower than the lowest sensing point 41a, maintaining liquid communication among the compartments at the bottom. The highest level sensing point 41d is used to inhibit the liquid level from getting higher than the highest sensing point 41d. In some embodiments, the effective inner space of the compartment which includes the liquid level sensor is slightly (insubstantially) smaller than that of the compartment which does not include the liquid level sensor, since the former compartment accommodates the liquid level sensor in the space. In some embodiments, the effective inner space of the compartment including the liquid level sensor is adjusted to be substantially the same as that of the compartment including no liquid level sensor.

In some embodiments, each compartment is provided with a gas inlet port and a gas outlet port, each being equipped with an on-off valve, for example. In FIG. 2, the compartment 49a has a gas inlet port 7a and a gas outlet port 8a on the top of the compartment. Likewise, the compartments 49b, 49c, 49d have gas inlet ports 7b, 7c, 7d, and gas outlet ports 8b, 8c, 8d, respectively. Each port is provided with an on-off valve 47. In some embodiments, the container body has no additional dividers other than the vertically-extending dividers dividing the compartments. In some embodiments, the container body has no additional ports other than the gas outlet port, the gas inlet port, the liquid material inlet port, and the liquid material discharge port.

As the liquid material, any suitable liquid materials can be stored in the container depending on its intended use. For example, the liquid material is a silicon-containing precursor such as TEOS, alkylsilanes, alkoxysilanes, aminosilanes, siloxanes, nitroalkylsiloxanes, etc. In some embodiments, the liquid material is supplied into the container body using a liquid material inlet port (not shown) provided on the top of any of the compartments. Further, in some embodiments, the liquid material can be discharged from the container body through a liquid material drain port (not shown) provided at the bottom of the container body.

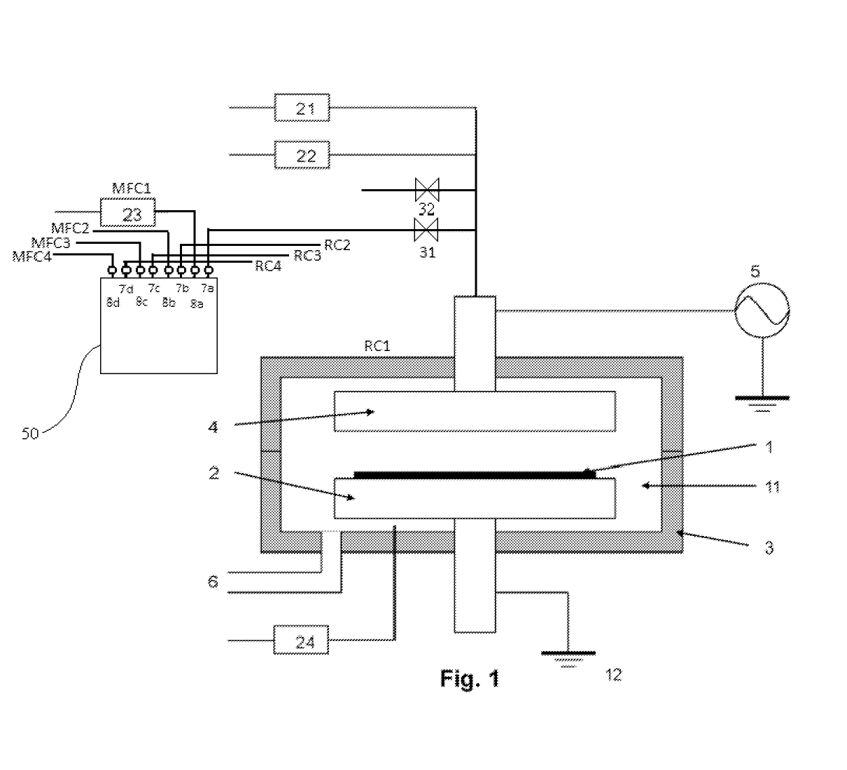

FIG. 1 is a schematic view of an exemplary apparatus combining a plasma enhanced ALD (atomic layer deposition) reactor and flow control system including the container, desirably in conjunction with controls programmed to conduct flow control valves and liquid level sensors described above, which can be used in an embodiment of the present invention.

In this example, by providing a pair of electrically conductive flat-plate electrodes 4, 2 in parallel and facing each other in the interior 11 of a reaction chamber 3, applying RF power 5 to one side, and electrically grounding 12 the other side, a plasma is excited between the electrodes. A temperature regulator is provided in a lower stage (which also serves as the lower electrode 2), and a temperature of a substrate 1 placed thereon is kept constant at a given temperature. The upper electrode 4 serves as a shower plate as well, and reaction gas and additive gas are introduced into the reaction chamber 3 through gas flow controllers 21, 22 (which may include mass flow controllers), respectively, and the shower plate. Also precursor gas is provided from a container 50 storing a liquid material inside and introduced into the reaction chamber 3 via a gas outlet port 7a, a pulse flow control valve 31 (for pulsing the flow) and the shower plate 4. Additionally, in the reaction chamber 3, an exhaust pipe 6 is provided through which gas in the interior 11 of the reaction chamber 3 is exhausted. Additionally, the reaction chamber is provided with a seal gas flow controller 24 to introduce seal gas into the interior 11 of the reaction chamber 3. A separation plate for separating a reaction zone and a transfer zone in the interior of the reaction chamber is omitted from this schematic figure. The seal gas is not required but is used in some embodiments for aiding in preventing reaction gas from communicating with the lower part of the chamber below the separation plate. For the pulse flow control valve 31, any pulse supply valve that is used for ALD (atomic layer deposition) can be used in an embodiment. For CVD, the pulse flow control valve 31 can be replaced by an on-off valve.

As illustrated in FIG. 2, the compartment 49a has the gas outlet port 7a and the gas inlet port 8a. The gas outlet port 7a is connected to the shower plate 4 through the valve 31 so that gas evaporated from the liquid material 48 in the compartment 49a can be introduced into the inside of the reaction chamber 3 together with carrier gas coming into the upper space of the compartment 49a through the gas inlet port 8a. In FIG. 1, the flow rate of carrier gas is controlled by a mass flow controller (MFC) 23 so as to control the quantity of the liquid material supplied to the reaction chamber 3. The carrier gas takes the vaporized liquid material from the upper space of the compartment and carries it to the reaction chamber 3. Likewise, the gas outlet ports 7b, 7c, 7d of the compartments 49b, 49c, 49d are connected to a second reaction chamber (RC2), third reaction chamber (RC3), and fourth reaction chamber (RC4), respectively. In this embodiment, this single integrated container can supply a precursor into four reaction chambers. The gas inlet ports 8b, 8c, 8d of the compartments 49b, 49c, 49d are connected to a second mass flow controller (MFC2), third mass flow controller (MFC3), fourth mass flow controller (MFC4), respectively, in order to introduce carrier gas into the respective upper spaces of the compartments at controlled flow rates and then to supply vaporized liquid material into RC2, RC3, RC4. In some embodiments, as the carrier gas, Ar, He, Kr, Xe, and/or other rare gases can be used singly or in combination.

A second precursor may be introduced into the reaction chamber 3 through a flow control valve 32 (a pulse flow control valve for ALD, an on-off valve for CVD) and the shower plate 4 using a second container (not shown) in a substantially similar manner to that in the first container 50. Likewise, the second precursor can be introduced into the other three reaction chambers. Likewise, a third precursor can be introduced into the four reaction chambers using a third container (not shown).

In some embodiments, the disclosed containers can be used in any suitable semiconductor-processing apparatuses such as those for plasma CVD, thermal CVD, plasma ALD, thermal ALD, etching, etc., having reaction chambers each processing a single wafer or multiple wafers.

In some embodiments, a reduction of cost and a reduction of footprint are substantial. For example, if there are four reactors, and three liquid materials are used, twelve conventional containers (e.g., $18,000 per container, a total of $216,000 for twelve containers, a footprint of 10,800 cm²) will be required. In contrast, if a container according to an embodiment of the present invention is used, only three containers (e.g., $30,000 per container, a total of $90,000, a footprint of 5,400 cm²) will be required, substantially reducing the cost and the footprint.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A container for containing a liquid material for processing a wafer, comprising:
a container body;
at least one divider vertically dividing the interior of the container body and defining compartments fluid-tightly sealed off from each other except for bottom portions of the compartments where the dividers have openings, said bottom portions being fluid-communicated with each other via the openings;
gas inlet ports for introducing gas to the respective compartments and gas outlet ports for discharging gas from the respective compartments, wherein one gas inlet port and one gas outlet port are attached to and fluid-communicated with a top portion of each compartment, said gas outlet ports being adapted to be connected to respective wafer-processing chambers; and
a liquid level sensor provided in one of the compartments for keeping a liquid surface of a liquid material above the bottom portions when the container is in use conditions.

2. The container according to claim 1, wherein the gas outlet ports are connected to the respective wafer-processing chambers.

3. The container according to claim 1, wherein the gas inlet ports are connected to respective mass flow controllers of carrier gas.

4. The container according to claim 1, wherein the openings have upper edges which are disposed under the lowest liquid level measurable by the liquid level sensor.

5. The container according to claim 1, wherein the peripheries of the dividers are welded to an inner wall of the container body except for bottom portions of the dividers so as to fluid-tightly seal off the compartments from each other except for the bottom portions of the compartments.

6. The container according to claim 1, wherein the compartments except for the bottom portions are substantially identical in their dimensions.

7. The container according to claim 1, wherein the container body is provided with a heater disposed outside the container body.

8. The container according to claim 7, wherein the compartments have shapes such that thermal energy from the heater is substantially equally supplied to each compartment.

9. The container according to claim 1, wherein the container body has liquid material inlet ports which are provided in the respective compartments.

10. The container according to claim 1, wherein the compartments store a liquid material whose liquid level is above upper edges of the openings of the dividers.

11. The container according to claim 1, where each of the gas inlet and gas outlet ports is provided with an on-off valve.

12. The container according to claim 1, wherein the one of the compartments is provided with the liquid level sensor, and all the other compartment(s) are/is provided with no liquid level sensors.

13. The container according to claim 1, wherein the compartments consist of a total of four compartments.

14. A container for containing a liquid material for processing a wafer, comprising:
a container body storing a liquid material;
at least one divider vertically extending from a top surface of the container body toward a bottom surface of the container body to a certain extent such that the divider divides the interior of the container body and defines compartments gas-tightly sealed off from each other except for bottom portions of the compartments, wherein gas phases of the liquid material in upper portions of the compartments are gas-tightly isolated and discrete from each other, whereas liquid phases under the gas phases of the liquid material are liquid-communicated with each other;
gas inlet ports for introducing gas to the respective compartments and gas outlet ports for discharging gas from the respective compartments, wherein one gas inlet port and one gas outlet port are attached to and gas-communicated with the upper portion of each compartment, said gas outlet ports being connected to respective wafer-processing chambers; and
a liquid level sensor provided in one of the compartments for keeping a liquid surface of the liquid material above the bottom portions.

15. The container according to claim 14, wherein the one of the compartments is provided with the liquid level sensor, and all the other compartment(s) are/is provided with no liquid level sensors.

16. The container according to claim 14, wherein the gas inlet ports are connected to respective mass flow controllers of carrier gas.

17. The container according to claim 14, wherein the liquid level sensor has a lowest sensing point which is above the bottom portions of the compartments.

18. The container according to claim 14, wherein the liquid material is a precursor for forming a film on a semiconductor wafer.

19. A wafer-processing apparatus comprising:
wafer-processing chambers being discrete from each other, each chamber being structured to process a wafer;
primary gas lines connected to the wafer-processing chambers;
secondary gas lines connected to the wafer-processing chambers; and
at least one container of claim 1 wherein the gas outlet ports are connected to the respective wafer-processing chambers via the primary gas lines.

20. The wafer-processing apparatus according to claim 14, wherein the wafer-processing chambers are plasma ALD reactors.
